(19) United States
(12) Patent Application Publication
(10) Pub. No.: US 2008/0117827 A1
(43) Pub. Date: May 22, 2008

(54) Method and system for verifying connectivity of logical link

(75) Inventors: Takehiko Matsumoto, Tokyo (JP); Shuichi Iida, Tokyo (JP); Tomoshige Funasaki, Tokyo (JP)

Correspondence Address: FOLEY AND LARDNER LLP;SUITE 500, 3000 K STREET NW, WASHINGTON, DC, 20007, US

(73) Assignee: NEC CORPORATION

(21) Appl. No.: 11/984,359

(22) Filed: Nov. 16, 2007

(30) Foreign Application Priority Data
Nov. 17, 2006 (JP) 2006-311142
Nov. 8, 2007 (JP) 2007-290576

(51) Int. Cl. G01R 31/08

(52) U.S. Cl. 370/244

(57) ABSTRACT

Verification of the connectivity of a logical link can be accomplished even in a network including a plurality of nodes that are connected through data link(s) and a control channel between adjacent nodes. A node that is the start point of a logical link to be verified transmits a logical link verification request message, over a control channel, to a node that is the end point of the logical link to be verified, thereby notifying that a connectivity verification test will begin. Thereafter, the start-point node transmits a physical link verification message (verification data) over the logical link to be verified. When notified through the control channel that the test will begin, the end-point node carries out the connectivity verification test, based on whether or not it can receive the verification data through the logical link to be verified. The end-point node returns a test result message to the start-point node.

### BACKGROUND OF THE INVENTION

1. Field of the Invention

This application is based upon and claims the benefit of priority from Japanese Patent Application No. 2006-311142, filed on Nov. 17, 2006 and Japanese Patent Application No. 2007-290576, filed on Nov. 8, 2007, the disclosure of which is incorporated herein in its entirety by reference.

The present invention generally relates to a technique for verification testing of the connectivity of a logical link composed of a plurality of data links (physical links). Particularly, the present invention relates to a method and system for logical link connectivity verification testing in a network including a plurality of nodes with each node being connected to an adjacent node through one or more data link and a control channel, such as a GMPLS (Generalized Multi-Protocol Label Switching) network.

2. Description of the Related Art

The GMPLS network is known as a network including a plurality of nodes that are connected through data link(s) and a control channel between adjacent nodes. In the GMPLS network, since the data and control planes are separated, there are some cases where a data link is abnormal even when a control channel is working normally. Therefore, in the GMPLS network, a connectivity verification test is performed on a data link by utilizing the data link connectivity verification function of the link management protocol (LMP).

For example, referring to FIG. 1A, a node 1 sends a BeginVerify message to a node 2 over a control channel to notify that a data link connectivity verification test will begin. This BeginVerify message contains the identifier of a data link (or the identifiers of data links) on which the connectivity verification test is performed, as well as the number of the data links.

Upon receipt of the BeginVerify message from the node 1, the node 2 sends back a BeginVerifyAck message to the node 1 over the control channel to notify that the node 2 is ready to perform the data link connectivity verification test.

The node 1 that has received the BeginVerifyAck message starts the data link connectivity verification test. Specifically, the node 1 sends a Test message to the node 2 over the data link or data links on which the connectivity verification test should be performed.

When the node 2 has normally received the Test message over the data link or data links, the node 2 sends a TestStatusSuccess message to the node 1 over the control channel. If the node 2 cannot normally receive the Test message even after a predetermined period of time has passed since receiving the BeginVerify message, then the node 2 sends a TestStatusFailure message to the node 1 over the control channel.

The node 1 that has received the TestStatusSuccess message or TestStatusFailure message sends a TestStatusAck message, which is a response to the received message, to the node 2 over the control channel.

When terminating the data link connectivity verification test, the node 1 sends an EndVerify message to the node 2 over the control channel and then receives an EndVerifyAck message from the node 2, whereby the data link connectivity verification test is complete.

As described above, in the exchange of the messages according to the LMP protocol, only the Test message is transmitted over the data link or data links, and all the other messages are exchanged over the control channel.

Incidentally, in the GMPLS network, when two arbitrary nodes communicate with each other, they need to set up a path beforehand on the data plane (a path is a continuous series of data links). In the GMPLS network, once a path is set up, the path serves as a single logical link, through which two nodes can communicate with each other.

For example, referring to FIG. 1B, in the case where nodes 1 and 3 communicate via a node 2, the nodes 1 and 3 set up, by using control channels C1 and C2, a logical link L1 composed of data links DL1 and DL2 and communicate with each other through this logical link L1.

Accordingly, it is preferable to perform a connectivity verification test also on a logical link composed of a plurality of data links. However, the data link connectivity verification function of the LMP protocol only provides for a function of verifying the connectivity of a data link between physically adjacent nodes. Therefore, it has been impossible to perform a connectivity verification test on a logical link.

On the other hand, an example of a technique for performing a connectivity verification test on a logical link is described in Japanese Patent Application Unexamined Publication No. H8-111682. This technique is to perform a connectivity verification test on a logical link connecting networks (including a plurality of switches). A start-point network, in response to a test command, sends a test message to an end-point network over a logical link to be verified.

An intermediate network present between the start-point and end-point networks determines whether or not a received message is the test message. If the received message is the test message, the intermediate network analyses the message and returns to the start-point network a response message that contains information about the state (normal, abnormal, or the like) of a network contained in the test message and that also contains information about the state of its own network. Further, the intermediate network forwards the received test message to a subsequent-stage network after adding the information about the state of its own network to the received test message.

The end-point network also determines whether or not a received message is the test message. If the received message is the test message, the end-point network returns to the start-point network a response message that contains information about the state of a network contained in the test message and that also contains information about the state of its own network. Thus, it is possible to acquire a grasp of the position and content of a failure on the logical link, based on the state information contained in the response message returned from each network to the start-point network.

The technique disclosed in Japanese Patent Application Unexamined Publication No. H8-111682 can be applied to a network which connects nodes through the same communication line(s) including data link(s) and control channel(s). However, this technique in question cannot be applied to a network, such as the GMPLS network, which includes a plurality of nodes that are connected through date link(s) and a control channel between adjacent nodes.

### SUMMARY OF THE INVENTION

Accordingly, an object of the present invention is to provide a method and system that enable logical link connectivity verification testing even in a network including a plurality of nodes that are connected through data link(s) and a control channel between adjacent nodes, such as the GMPLS network.

The present invention provides a method for verifying connectivity of a logical link in a network including a plurality of nodes which are connected through at least one data link and a control channel between adjacent nodes, wherein a test logical link whose connectivity is to be verified is set up between a start-point node and an end-point node via at least one node in the network. The start-point node notifies the end-point node through control channels that a connectivity verification test begins; and transmits arbitrary verification data through the test logical link. The end-point node performs the connectivity verification test based on whether or not the verification data is successfully received through the test logical link; and transmits a test result to the start-point node through the control channels.

As described above, according to the present invention, even in a network including a plurality of nodes that are connected through at least one data link and a control channel between adjacent nodes, such as the GMPLS network, a logical link connectivity verification test can be performed.

### BRIEF DESCRIPTION OF THE DRAWINGS

FIG. 1A is a sequence diagram to describe a conventional connectivity verification test on a data link.

FIG. 1B is a block diagram to describe a logical link in a GMPLS network.

FIG. 2 is a block diagram showing an example of a network to describe an exemplary embodiment of the present invention.

FIG. 3 is a block diagram showing an example of a configuration of a node used in a logical link connectivity verification system according to a first exemplary embodiment of the present invention.

FIG. 4A is a diagram showing an example of data stored in a logical link information memory in a node N2 used in the first exemplary embodiment.

FIG. 4B is a diagram showing an example of data stored in a data link information memory in the node N2 used in the first exemplary embodiment.

FIG. 4C is a diagram showing an example of data stored in a cross-connect setting information memory in the node N2 used in the first exemplary embodiment.

FIG. 5 is a block diagram showing a schematic configuration of the logical link connectivity verification system according to the first exemplary embodiment of the present invention.

FIG. 6 is a sequence diagram to describe operation according to the first exemplary embodiment shown in FIG. 5.

FIG. 7A is a block diagram showing a first example of a logical link connectivity verification system according to a second exemplary embodiment of the present invention.

FIG. 7B is a block diagram showing a second example of the logical link connectivity verification system according to the second exemplary embodiment of the present invention.

FIG. 8A is a diagram showing an example of data stored in a logical link information memory in a node N53 used in the second exemplary embodiment.

FIG. 8B is a diagram showing an example of data stored in a data link information memory in the node N53 used in the second exemplary embodiment.

FIG. 8C is a diagram showing an example of data stored in a cross-connect setting information memory in the node N53 used in the second exemplary embodiment.

FIG. 9 is a sequence diagram to describe operation according to the second exemplary embodiment.

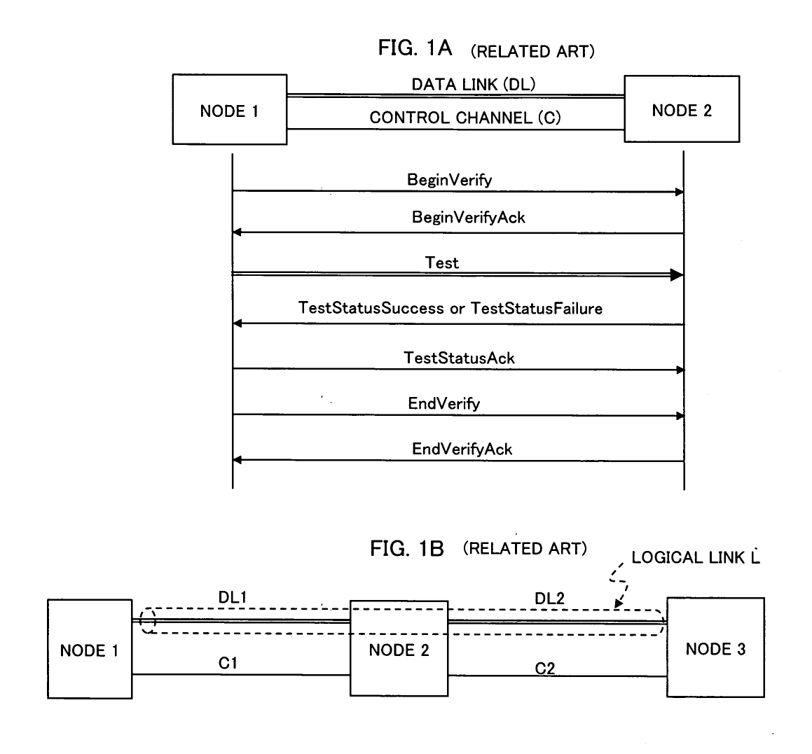

### DETAILED DESCRIPTION OF THE PREFERRED EMBODIMENTS

Hereinafter, a detailed description will be given of preferred embodiments of the present invention, with reference to the accompanied drawings.

### 1. First Exemplary Embodiment

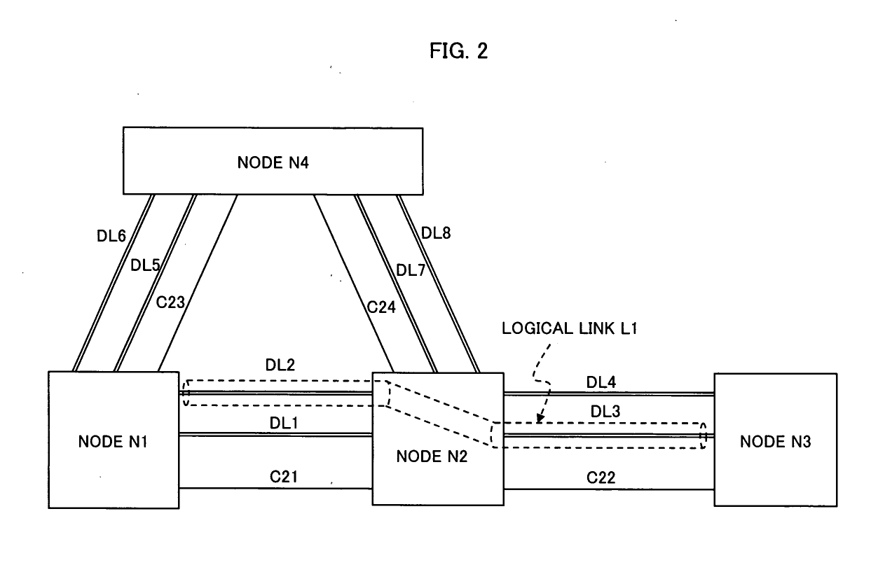

The present invention is applicable to a network including a plurality of nodes that are connected through at least one data link and a control channel between adjacent nodes, such as the GMPLS network. To avoid complexity, a description will be given below of the case where the present invention is applied to a GMPLS network shown in FIG. 2, as an example.

The GMPLS network shown as an example in FIG. 2 includes a plurality of nodes N1 to N4. It is assumed that the nodes N1 and N2 are connected through data links DL1 and DL2 and a control channel C21, that the nodes N2 and N3 are connected through data links DL3 and DL4 and a control channel C22, that the nodes N1 and N4 are connected through data links DL5 and DL6 and a control channel C23, and that the nodes N2 and N4 are connected through data links DL7 and DL8 and a control channel C24.

The data links DL1 to DL8 are links along which actual data (user data) flow, and are generally implemented by optical fiber. Moreover, in general, two or more data links are present between adjacent nodes. On the other hand, the control channels C21 to C24 are links along which messages to control the GMPLS network flow, such as those for routing and signaling. In addition, each of the nodes N1 to N4 has a switching function, routing function, signaling function and the like, and has ports to which the corresponding ones of the data links DL1 to DL8 and control channels C21 to C24 are connected.

Here, a description will be given of the case where a connectivity verification test is performed on a logical link L1, which is set up between the nodes N1 and N3 via the node N2 as described later.

### 1.1) System Configuration

First, a description will be given of a node used in a logical link connectivity verification system according to a first exemplary embodiment of the present invention. The nodes N1 to N4 shown in FIG. 2 have similar circuit configurations. Therefore, the circuit configuration of the node N2 will be representatively described below.

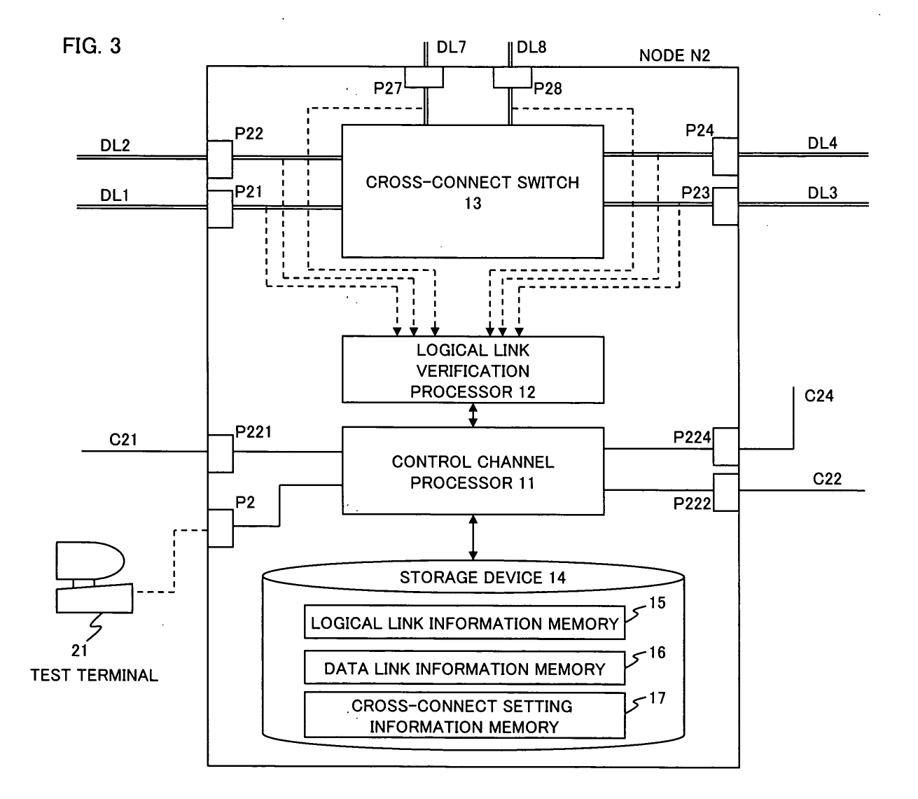

Referring to FIG. 3, the node N2 includes a control channel processor 11, a logical link verification processor 12, a cross-connect switch 13, a storage device 14, ports P21 to P24, P27 and P28 to which data links DL1 to DL4, DL7 and DL8 are connected respectively, ports P221, P222 and P224 to which control channels C21, C22 and C24 are connected respectively, and a test port P2 for use in testing to which a test terminal 21, which is implemented by a personal computer or the like, can be connected.

The storage device 14 includes a logical link information memory 15, a data link information memory 16, and a cross-connect setting information memory 17.

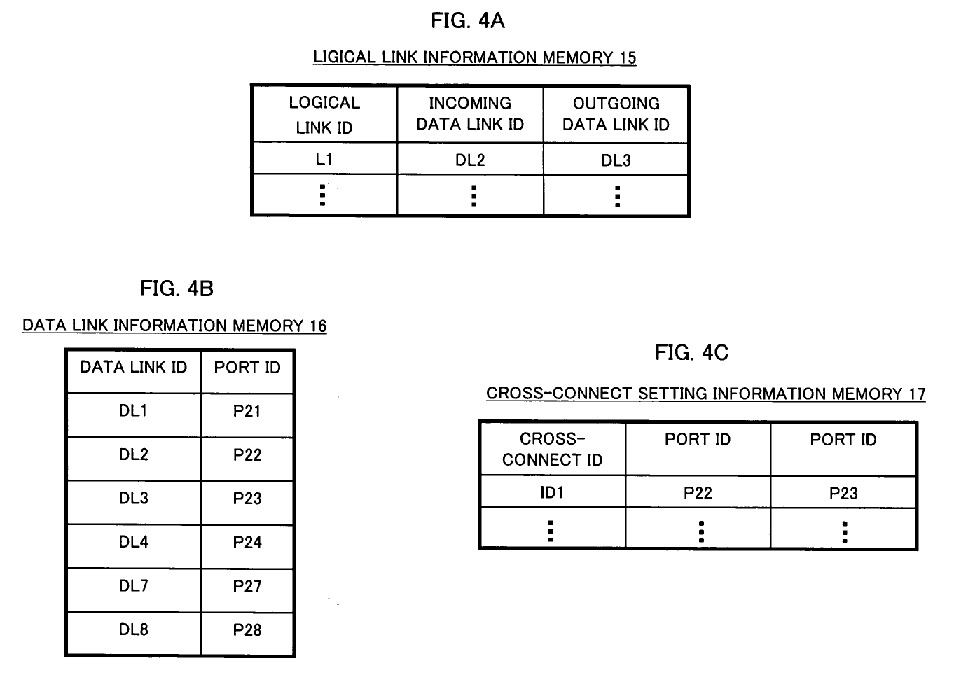

The logical link information memory 15 stores logical link information for associating a logical link with a data link that is connected to the node N2 among the data links constituting the logical link. For example, assuming that a logical link L1 composed of the data links DL2 and DL3 is set up between the nodes N1 and N3 as shown in FIG. 2, the content stored in the logical link information memory 15 of the node N2 is as shown in FIG. 4A. The example shown in FIG. 4A indicates that, among the data links constituting the logical link L1, the data link DL2 is connected to the node N2 as an incoming data link and the data link DL3 is connected to the node N2 as an outgoing data link. Note that, in the node N1, which is the start point of the logical link L1, only an entry “DL2” in the outgoing data link ID is made, associated with the logical link ID “L1”. In the node N3, which is the end point of the logical link L1, only an entry “DL3” in the incoming data link ID is made, associated with the logical link ID “L1”.

Moreover, the data link information memory 16 stores data link information for associating a data link with a port. FIG. 4B is a diagram showing an example of the content stored in the data link information memory 16 of the node N2. The example shown in FIG. 4B indicates that the data links DL1 to DL4, DL7 and DL8 are connected to the ports P21 to P24, P27 and P28, respectively.

Furthermore, the cross-connect setting information memory 17 stores setting information regarding a cross-connect switch inside the node N2. FIG. 4C is a diagram showing an example of the content stored in the cross-connect setting information memory 17 of the node N2. The example shown in FIG. 4C indicates that the ports P22 and P23 are connected to each other by a cross-connect switch.

The control channel processor 11 has conventionally existing functions, such as a function of setting up a logical link in accordance with logical link setup instructions sent over the control channels C21 and C22.

In addition to those conventionally existing functions, the control channel processor 11 further has the following functions.
Function of instructing to begin a test: in the case where a node is the start-point node of a logical link to be subjected to a connectivity verification test (hereinafter, referred to as “test logical link”), with the test terminal 21 being connected to the test port P2 (here, in the case of the node N1), it is assumed that an instruction to begin a test (“begin test” instruction), containing the logical link ID of the test logical link, is input from the test terminal 21. In this case, the control channel processor 11 of the node in question notifies the end-point node of the test logical link, over a control channel, that a connectivity verification test will begin, and also outputs to the logical link verification processor 12 of its own node an instruction to transmit verification data (“transmit verification data” instruction). Incidentally, the “transmit verification data” instruction contains the port ID of a port connected to a data link that will transmit the verification data.
Function of instructing to perform the test: when it is notified through a control channel that a connectivity verification test on the test logical link will begin, the control channel processor 11 of a node (here, each of the nodes N2 and N3) outputs to the logical link verification processor 12 of its own node a “verify” instruction to instruct the logical link verification processor 12 to perform the connectivity verification test on the test logical link. Incidentally, the “verify” instruction contains the port ID of a port connected to a data link that is a constituent of the test logical link.
Function of returning a test result: the control channel processor 11 of a node (here, each of the nodes N2 and N3) returns a result of the test performed by the logical link verification processor 12 to the start-point node of the test logical link over the control channel.

The logical link verification processor 12 has the following functions.
Function of transmitting the verification data to the port designated by the “transmit verification data” instruction from the control channel processor 11. Note that the verification data may be arbitrary one.
Function of performing the connectivity verification test based on whether or not the data can be transmitted/received through the port designated by the “verify” instruction from the control channel processor 11.

Each node having such functions can be implemented by using a computer. In the case of using a computer, a node is implemented as follows, for example. Any one of a disk, semiconductor memory, and other recording media storing a program for causing a computer to function as the control channel processor 11 and logical link verification processor 12 is prepared, and the computer is allowed to read the program. The computer controls its own operation in accordance with the read program, thereby implementing the control channel processor 11 and logical link verification processor 12 on itself.

### 1.2) Operation

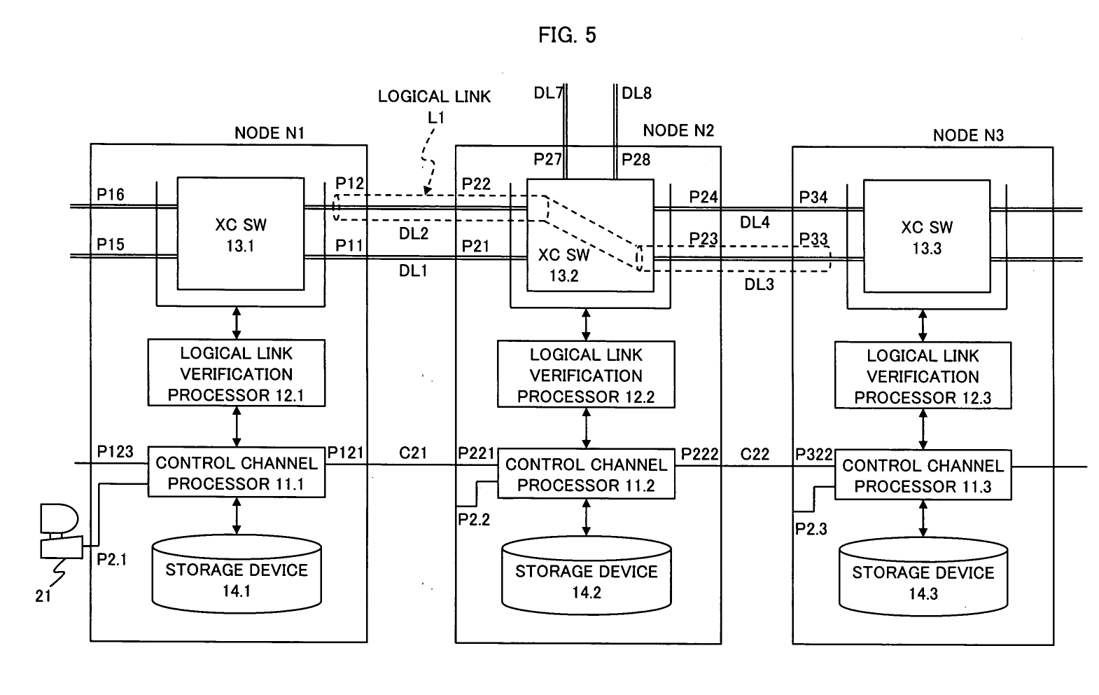

FIG. 5 is a block diagram showing a schematic configuration of the logical link connectivity verification system according to the first exemplary embodiment of the present invention. Here, a connectivity verification test is performed on the logical link L1 set up between the nodes N1 and N3 via the node N2. Incidentally, it is assumed that the control channel processor 11, logical link verification processor 12, cross-connect switch 13, storage device 14, logical link information memory 15, data link information memory 16, and cross-connect setting information memory 17 of the node Nx (x=1, 2 or 3) are denoted by reference numerals 11.x to 17.x, respectively. Similarly, it is assumed that the test port P2 is denoted by P2.x. Moreover, it is assumed that ports connected to the data links DL1 to DL4 are denoted by Px1 to Px4, respectively, and that ports connected to the control channels C21 and C22 are denoted by Px21 and Px22, respectively.

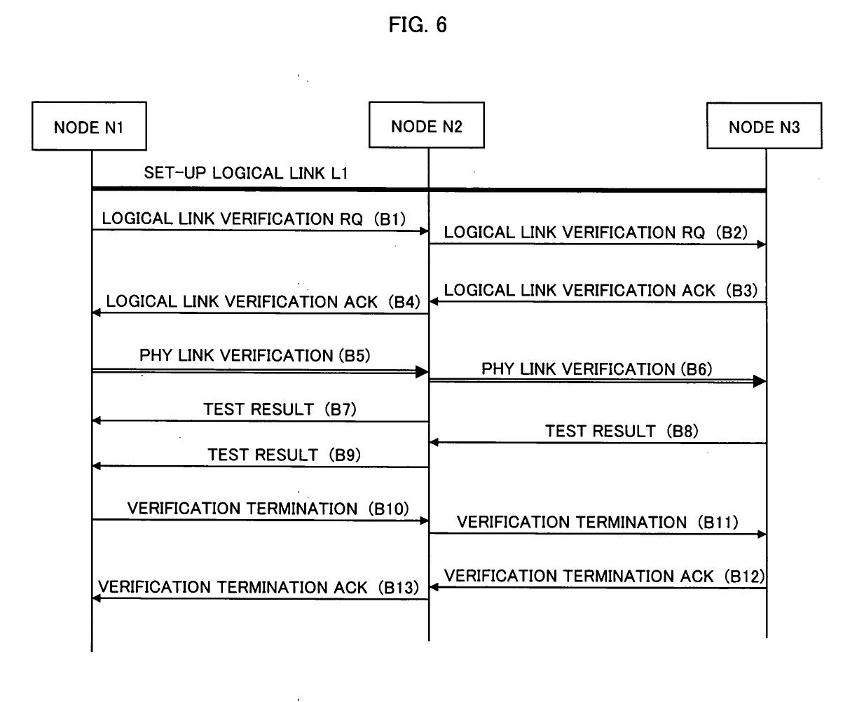

FIG. 6 is a sequence diagram to describe the operation in the case of performing a connectivity verification test on the logical link L1 shown in FIG. 5.

FIG. 6 shows messages exchanged between the nodes N1, N2 and N3 after the logical link L1 has been set up. Note that the messages exchanged in steps B5 and B6 are transmitted over the data links, and the messages exchanged in steps B1 to B4 and B7 to B13 are transmitted over the control channels.

When a connectivity verification test on the logical link L1 is performed, a person conducting the test connects the test terminal 21 to the node N1, the start-point node of the logical link L1, and enters a “begin test” instruction. This “begin test” instruction contains “L1”, the logical link ID of the logical link L1.

Upon receipt of the “begin test” instruction containing the logical link ID “L1” from the test terminal 21 as an input, the control channel processor 11.1 of the node N1 first transmits a logical link verification request message to the node N2 over the control channel C21, to notify that the connectivity verification test on the logical link L1 will begin (step B1). This logical link verification request message contains the logical link ID “L1”.

Upon receipt of the logical link verification request massage containing the logical link ID “L1” through the control channel C21, the control channel processor 11.2 of the node N2, since the node N2 is not the end-point node of the logical link L1, transmits the logical link verification request message to the node N3 over the control channel C22 (step B2). Further, the control channel processor 11.2 of the node N2 outputs a “verify” instruction to the logical link verification processor 12.2. This “verify” instruction contains “P22” and “P23”, the port IDs of ports P22 and P23 of the node N2 connected to the incoming data link DL2 and outgoing data link DL3, respectively, which constitute the logical link L1. At this instruction, the logical link verification processor 12.2 begins monitoring the ports P22 and P23. Specifically, the logical link verification processor 12.2 monitors whether or not data is input through the port P22, and also monitors whether or not data is output through the port 23. When detecting that data is input through the port P22, or when detecting that data is output through the port P23, the logical link verification processor 12.2 provides notification to that effect to the control channel processor 11.2. Incidentally, the port IDs “P22” and “P23” of the ports P22 and P23 connected to the incoming data link DL2 and outgoing data link DL3, which constitute the logical link L1, can be obtained from the contents stored in the logical link information memory 15.2 and data link information memory 16.2.

Upon receipt of the logical link verification request message through the control channel C22, the control channel processor 11.3 of the node N3, since the node N3 is the end-point node of the logical link L1, transmits a logical link verification acknowledgment message to the node N2 (step B3). Further, the control channel processor 11.3 of the node N3 outputs a “verify” instruction to the logical link verification processor 12.3. This “verify” instruction contains “P33”, the port ID of a port P33 of the node N3 connected to the incoming data link DL3, which is a constituent of the logical link L1. At this instruction, the logical link verification processor 12.3 begins monitoring the port P33. When detecting that data is input through the port P33, the logical link verification processor 12.3 provides notification to that effect to the control channel processor 11.3.

Upon receipt of the logical link verification acknowledgment message through the control channel C22, the control channel processor 11.2 of the node N2 transmits the message to the node N1 (step B4).

Upon receipt of the logical link verification acknowledgment message, the control channel processor 11.1 of the node N1 outputs a “verify” instruction to the logical link verification processor 12.1. This “verify” instruction contains “P12”, the port ID of a port P12 of the node N1 connected to the data link DL2, which is a constituent of the logical link L1. At this instruction, the logical link verification processor 12.1 of the node N1 transmits a physical link verification message (verification data) through the port P12 over the data link DL2. Note that the content of the physical link verification message may be arbitrary.

When arriving at the node N2, the physical link verification message is transmitted over to the data link DL3 via the port P22, cross-connect switch 13.2, and port P23 (step B6). Thereby, the logical link verification processor 12.2 of the node N2 detects that the data is input through the port P22 and that the data is output through the port P23, and provides notification to that effect to the control channel processor 11.2. If the control channel processor 11.2 receives this notification within a predetermined period of time of receiving the logical link verification request message, the control channel processor 11.2 returns a test result message indicating success in the test to the start-point node N1 over the control channel C21. On the other hand, if the control channel processor 11.2 cannot receive the notification within the predetermined period of time, the control channel processor 11.2 returns a test result message indicating failure in the test to the start-point node N1 (step B7). Note that the test result message contains the node ID of the node N2. Upon receipt of the test result message, the control channel processor 11.1 of the node N1 transmits the message to the test terminal 21, which then displays the test result message transmitted from the node N1 on a display section (not shown).

In addition, similar processing to the processing performed in the node N2 is also performed in the node N3, and a test result message is transmitted to the node N2 over the control channel C22 (step B8). The control channel processor 11.2 of the node N2 transmits the test result message transmitted from the node N3 to the start-point node N1 over the control channel C21 (step B9).

Upon receipt of the test result message originating from the end-point node N3, the control channel processor 11.1 of the node N1 transmits the message to the test terminal 21 and also transmits a verification termination message to the nodes N2 and N3 (steps B10 and B11).

Upon receipt of the verification termination message, the control channel processor 11.3 of the node N3 transmits a verification termination acknowledgment message to the start-point node N1 via the node N2 (steps B12 and B13). At this point, the connectivity verification test in the direction from the node N1 toward the node N3 is complete. Subsequently, a connectivity verification test in the direction from the node N3 toward the node N1 is performed in a similar manner, whereby the connectivity of the logical link L1 in both directions is verified. Thus, the connectivity verification test on the logical link L1 is complete.

### 1.3) Advantages

According to the first exemplary embodiment, a logical link connectivity verification test can be performed even in a network including a plurality of nodes that are connected through data link(s) and a control channel between adjacent nodes, such as the GMPLS network. A reason for this is that the start-point node N1 of the test logical link L1 notifies the end-point node N3 of the test logical link L1, over the control channels C21 and C22, that a connectivity verification test on the test logical link L1 will begin. That is, the end-point node N3 can recognize that a connectivity verification test on the test logical link L1 will begin, based on the notification sent from the start-point node N1 over the control channels C21 and C22. Accordingly, it is possible to perform a logical link connectivity verification test even in a network including a plurality of nodes that are connected through data link(s) and a control channel between adjacent nodes.

### 2. Second Exemplary Embodiment

In the above-described first exemplary embodiment, a connectivity verification test is performed on a logical link composed of a plurality of data links. However, in a second exemplary embodiment of the present invention, a connectivity verification test is performed on a logical link composed of a plurality of logical links.

### 2.1) System Configuration

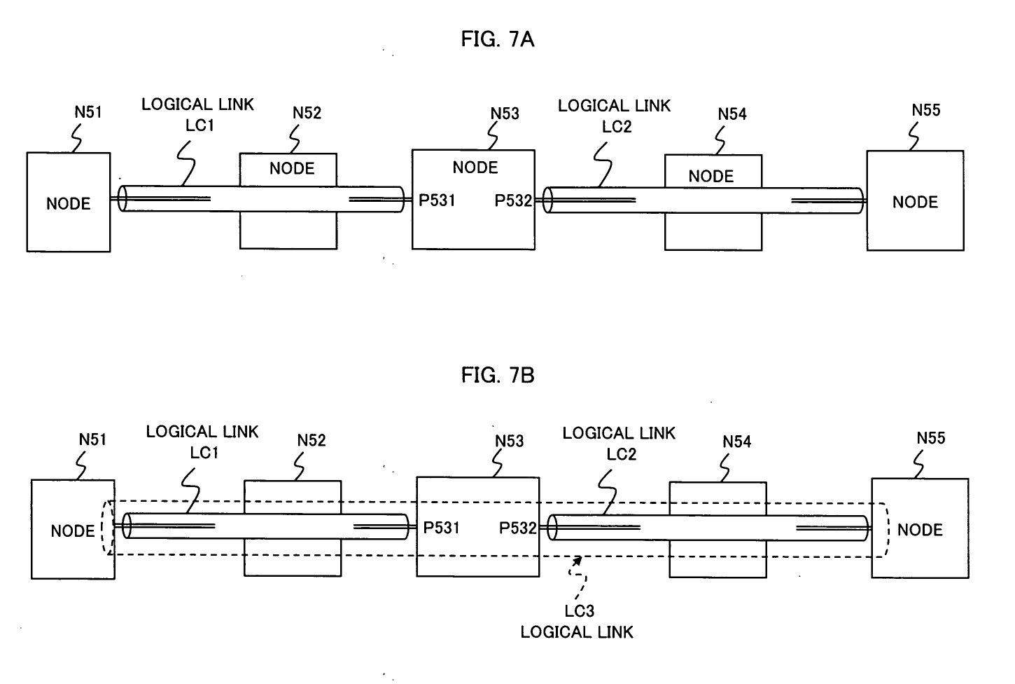

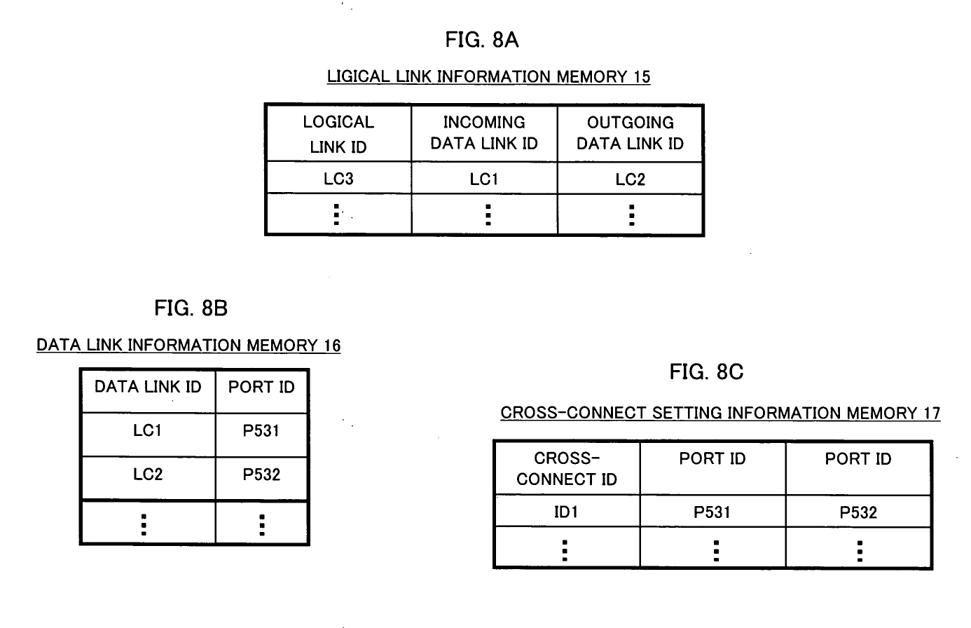

FIG. 7A is a schematic diagram showing a network including five nodes N51 to N55 in which two logical links LC1 and LC2 exist. Note that each of the nodes N51 to N55 has a similar configuration to the node N2 shown in FIG. 3. The logical link LC1 is set up between the nodes N51 and N53 via the node N52, and the logical link LC2 is set up between the nodes N53 and N55 via the node N54. FIG. 7B shows an example in which a new logical link LC3 is created by using the logical links LC1 and LC2 shown in FIG. 7A. Each logical link once created acts like a data link. FIGS. 8A to 8C show examples of the contents stored in a logical link information memory 15, data link information memory 16, and cross-connect setting information memory 17 of the node N53 shown in FIG. 7B, respectively. Since the logical link LC3 uses the logical links LC1 and LC2 in a similar manner to the way of using data links, the logical link IDs of the logical links LC1 and LC2, “LC1” and “LC2”, are stored as data link IDs in each of the logical link information memory 15 and data link information memory 16. Although not shown in FIG. 8A, logical link information for associating a logical link with a data link is also stored in the logical link information memory 15, as in FIG. 4A. Further, although not shown in FIG. 8B, data link information for associating a data link with a port is also stored in the data link information memory 16, as in FIG. 4B.

### 2.3) Operation

Next, operation according to the second exemplary embodiment will be described. It is assumed that the logical link LC1 has already been set up between the nodes N51 and N53 via the node N52, and that the logical link LC2 has already been set up between the nodes N53 and N55 via the node N54, and further that the logical link LC3 has already been set up using the logical links LC1 and LC2.

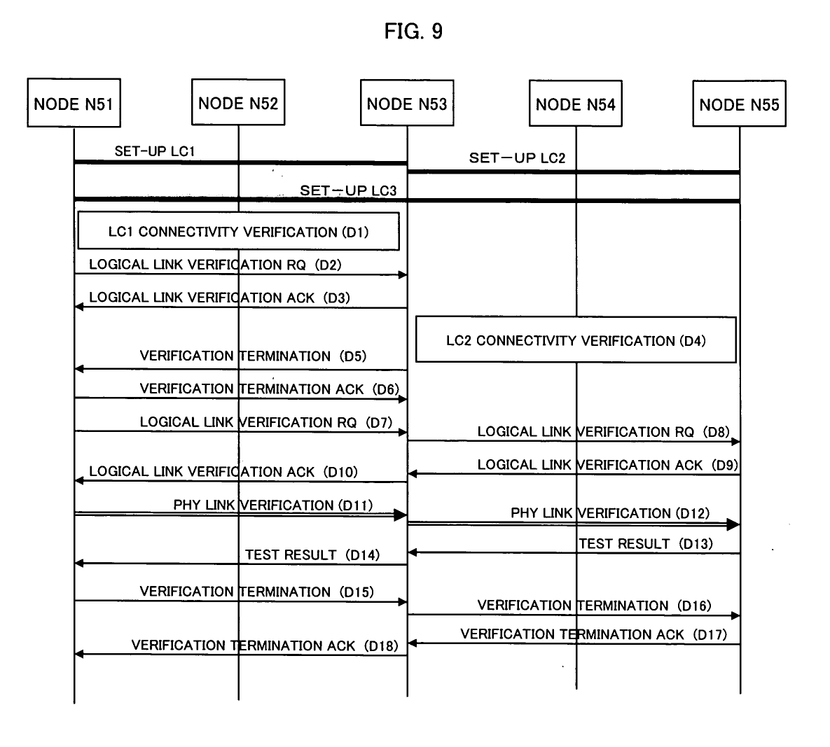

Referring to FIG. 9, in a step D1, a connectivity verification test on the logical link LC1 is first performed through a similar procedure to the procedure shown in FIG. 6. When the connectivity of the logical link LC1 is confirmed, then, in a step D2, the node N51 transmits a logical link verification request message to the node N53.

Next, in a step D3, the node N53 transmits a logical link verification acknowledgment message to the node N51.

Next, in a step D4, a connectivity verification test on the logical link LC2 is performed. When the connectivity of the logical link LC2 is confirmed, then, in a step D5, the node N53 transmits a logical link verification termination message to the node N51, and in a step D6, the node N51 transmits a logical link verification termination acknowledgment message to the node N53.

In subsequent steps D7 to D18, the connectivity of the logical link LC3 is verified.

Specifically, in the step D7, the node N51 transmits a logical link verification request message to the node N53. In the step D8, the node N53 forwards the logical link verification request message to the node N55. The logical link verification request message contains “LC3”, the logical link ID of the test logical link.

Next, in the step D9, the node N55 transmits a logical link verification acknowledgment message to the node N53, and in the step D10, the node N53 forwards the logical link verification acknowledgment message to the node N51.

Next, in the step D11, the node N51 transmits a physical link verification message to the node N53 over the logical link LC1 (data link).

Next, in the step D12, the node N53 transmits the physical link verification message to the node N55 over the logical link LC2 (data link).

The node N55 transmits to the node N53 a test result message indicating success in the connectivity verification test when the connectivity of the logical link LC3 (data link) can be confirmed, but transmits a test result message indicating failure in the connectivity verification test when the connectivity cannot be confirmed (step D13).

Next, in the step D14, the node N53 forwards the test result message to the node N51.

Next, in the step D15, the node 51 transmits a verification termination message to the node N53, and in the step D16, the node N53 forwards the verification termination message to the node N55.

Next, in the step D17, the node N55 transmits a verification termination acknowledgment message to the node N53, and in the step D18, the node N53 forwards the verification termination acknowledgment message to the node N51.

### 2.3) Advantages

According to the second exemplary embodiment, it is possible to verify the connectivity of the test logical link LC3 composed of the plurality of logical links LC1 and LC2. A reason for this is that the start-point node N51 of the test logical link LC3 notifies the end-point node N55 of the test logical link LC3, over the control channels, that a connectivity verification test will begin.

The present invention is suitable to the case where a logical link connectivity verification test is performed in a network including a plurality of nodes that are connected through data link(s) and a control channel between adjacent nodes, such as the DMPLS network.

### 3. Various Aspects

As described before, an object of the present invention is to provide a method and system that enable logical link connectivity verification testing even in a network including a plurality of nodes that are connected through data link(s) and a control channel between adjacent nodes, such as the GMPLS network.

To achieve the object, the present invention provides a method for verifying connectivity of a logical link in a network including a plurality of nodes which are connected through at least one data link and a control channel between adjacent nodes, wherein a test logical link whose connectivity is to be verified is set up between a start-point node and an end-point node via at least one node in the network. The start-point node notifies the end-point node through control channels that a connectivity verification test begins; and transmits arbitrary verification data through the test logical link. The end-point node performs the connectivity verification test based on whether or not the verification data is successfully received through the test logical link; and transmits a test result to the start-point node through the control channels.

According to the present invention, even in a network including a plurality of nodes that are connected through at least one data link and a control channel between adjacent nodes, such as the GMPLS network, a logical link connectivity verification test can be performed. A reason for this is that a node that is the start point of a logical link to be verified notifies a node that is the end point of the logical link, over a control channel, that a connectivity verification test on the logical link to be verified will begin. That is, the end-point node can recognize that a logical link connectivity verification test will begin, based on the notification sent from the start-point node over the control channel. Accordingly, it is possible to perform a logical link connectivity verification test even in a network including a plurality of nodes that are connected through data link(s) and a control channel between adjacent nodes, such as the GMPLS network.

In an exemplary embodiment, an intermediate node between the start-point node and the end-point node is also notified by the start-point node that the connectivity verification test begins. The intermediate node may perform the connectivity verification test based on whether or not the verification data is successfully received through the test logical link and then transmits a test result to the start-point node through control channels. The test logical link may be formed by a plurality of logical links. Preferably, the network may be a GMPLS (Generalized Multi-Protocol Label Switching) network.

According to another aspect of the present invention, a system for verifying connectivity of a logical link in a network including a plurality of nodes which are connected through at least one data link and a control channel between adjacent nodes, wherein a test logical link whose connectivity is to be verified is set up between a start-point node and an end-point node via at least one node in the network, wherein each of the plurality of nodes includes a verification section. The verification section, when receiving an instruction of a connectivity verification test of the test logical link, notifies the end-point node through control channels that a connectivity verification test begins and transmits arbitrary verification data through the test logical link. When notified that the connectivity verification test begins, the verification section performs the connectivity verification test based on whether or not the verification data is successfully received through the test logical link and transmits a test result to the start-point node through the control channels.

The verification section may include: a logical link verification processing section for transmitting arbitrary verification data through a test logical link indicated by a verification data transmission instruction and performing the connectivity verification test based on whether or not verification data is successfully received through a test logical link indicated by a verification instruction; and a control channel processing section for, when the a test logical link is indicated, notifying the end-point node through control channels that the connectivity verification test begins and outputting the verification data transmission instruction to the logical link verification processing section and, when notified through the control channels that the connectivity verification test begins, outputting the verification instruction to the logical link verification processing section, and transmitting a test result to the start-point node of the test logical link through control channels.

According to still another aspect of the present invention, a node in a network including a plurality of nodes which are connected through at least one data link and a control channel between adjacent nodes, wherein a test logical link whose connectivity is to be verified is set up between a start-point node and an end-point node via at least one node in the network, includes a verification section. When receiving an instruction of a connectivity verification test of the test logical link, the verification section notifies the end-point node through control channels that a connectivity verification test begins and transmits arbitrary verification data through the test logical link; and when notified through control channels that the connectivity verification test begins, the verification section performs the connectivity verification test based on whether or not the verification data is successfully received through the test logical link and transmits a test result to the start-point node through the control channels.

The node may be realized by a program running on a computer.

The present invention may be embodied in other specific forms without departing from the spirit or essential characteristics thereof. The above-described exemplary embodiments are therefore to be considered in all respects as illustrative and not restrictive, the scope of the invention being indicated by the appended claims rather than by the foregoing description, and all changes which come within the meaning and range of equivalency of the claims are therefore intended to be embraced therein.

1. A method for verifying connectivity of a logical link in a network including a plurality of nodes which are connected through at least one data link and a control channel between adjacent nodes, wherein a test logical link whose connectivity is to be verified is set up between a start-point node and an end-point node via at least one node in the network, comprising:
at the start-point node,
a) notifying the end-point node through control channels that a connectivity verification test begins;
b) transmitting arbitrary verification data through the test logical link;
at the end-point node,
c) performing the connectivity verification test based on whether or not the verification data is successfully received through the test logical link; and
d) transmitting a test result to the start-point node through the control channels.

2. The method according to claim 1, wherein in the a), an intermediate node between the start-point node and the end-point node is also notified by the start-point node that the connectivity verification test begins, wherein the method further comprises:
at the intermediate node,
performing the connectivity verification test based on whether or not the verification data is successfully received through the test logical link; and
transmitting a test result to the start-point node through control channels.

3. The method according to claim 1, wherein the test logical link is formed by a plurality of logical links.

4. The method according to claim 1, wherein the network is a GMPLS (Generalized Multi-Protocol Label Switching) network.

5. A system for verifying connectivity of a logical link in a network including a plurality of nodes which are connected through at least one data link and a control channel between adjacent nodes, wherein a test logical link whose connectivity is to be verified is set up between a start-point node and an end-point node via at least one node in the network, wherein each of the plurality of nodes includes a verification section, wherein
when receiving an instruction of a connectivity verification test of the test logical link, the verification section notifies the end-point node through control channels that a connectivity verification test begins and transmits arbitrary verification data through the test logical link; and
when notified that the connectivity verification test begins, the verification section performs the connectivity verification test based on whether or not the verification data is successfully received through the test logical link and transmits a test result to the start-point node through the control channels.

6. The system according to claim 5, wherein
the verification section also notifies an intermediate node between the start-point node and the end-point node through control channels that the connectivity verification test begins and,
when notified that the connectivity verification test begins and if its own node is an intermediate node, the verification section performs the connectivity verification test based on whether or not the verification data is successfully received through the test logical link and transmits a test result to the start-point node through the control channels.

7. The system according to claim 5, wherein the logical link is formed by a plurality of logical links.

8. The system according to claim 5, wherein the verification section comprises:
a logical link verification processing section for transmitting arbitrary verification data through a test logical link indicated by a verification data transmission instruction and performing the connectivity verification test based on whether or not verification data is successfully received through a test logical link indicated by a verification instruction; and
a control channel processing section for, when the a test logical link is indicated, notifying the end-point node through control channels that the connectivity verification test begins and outputting the verification data transmission instruction to the logical link verification processing section and, when notified through the control channels that the connectivity verification test begins, outputting the verification instruction to the logical link verification processing section, and transmitting a test result to the start-point node of the test logical link through control channels.

9. The system according to claim 5, wherein the network is a GMPLS (Generalized Multi-Protocol Label Switching) network.

10. A node in a network including a plurality of nodes which are connected through at least one data link and a control channel between adjacent nodes, wherein a test logical link whose connectivity is to be verified is set up between a start-point node and an end-point node via at least one node in the network,
the node comprising a verification section, wherein when receiving an instruction of a connectivity verification test of the test logical link, the verification section notifies the end-point node through control channels that a connectivity verification test begins and transmits arbitrary verification data through the test logical link; and when notified through control channels that the connectivity verification test begins, the verification section performs the connectivity verification test based on whether or not the verification data is successfully received through the test logical link and transmits a test result to the start-point node through the control channels.

11. The node according to claim 10, wherein
the verification section also notifies an intermediate node between the start-point node and the end-point node through control channels that the connectivity verification test begins and,
when notified that the connectivity verification test begins and if its own node is an intermediate node, the verification section performs the connectivity verification test based on whether or not the verification data is successfully received through the test logical link and transmits a test result to the start-point node through the control channels.

12. The node according to claim 10, wherein the logical link is formed by a plurality of logical links.

13. The node according to claim 10, wherein the verification section comprises:
a logical link verification processing section for transmitting arbitrary verification data through a test logical link indicated by a verification data transmission instruction and performing the connectivity verification test based on whether or not verification data is successfully received through a test logical link indicated by a verification instruction; and
a control channel processing section for, when the a test logical link is indicated, notifying the end-point node through control channels that the connectivity verification test begins and outputting the verification data transmission instruction to the logical link verification processing section and, when notified through the control channels that the connectivity verification test begins, outputting the verification instruction to the logical link verification processing section, and transmitting a test result to the start-point node of the test logical link through control channels.

14. The node according to claim 10, wherein the network is a GMPLS (Generalized Multi-Protocol Label Switching) network.

15. A computer-readable media storing a program which instructs a computer to function as a node in a network including a plurality of nodes which are connected through at least one data link and a control channel between adjacent nodes, wherein a test logical link whose connectivity is to be verified is set up between a start-point node and an end-point node via at least one node in the network,
the program instructs the computer to function as a verification section, wherein when receiving an instruction of a connectivity verification test of the test logical link, the verification section notifies the end-point node through control channels that a connectivity verification test begins and transmits arbitrary verification data through the test logical link; and when notified through control channels that the connectivity verification test begins, the verification section performs the connectivity verification test based on whether or not the verification data is successfully received through the test logical link and transmits a test result to the start-point node through the control channels.

16. The computer-readable media according to claim 15, wherein
the verification section also notifies an intermediate node between the start-point node and the end-point node through control channels that the connectivity verification test begins and,
when notified that the connectivity verification test begins and if its own node is an intermediate node, the verification section performs the connectivity verification test based on whether or not the verification data is successfully received through the test logical link and transmits a test result to the start-point node through the control channels.

17. The computer-readable media according to claim 15, wherein the verification section comprises:
a logical link verification processing section for transmitting arbitrary verification data through a test logical link indicated by a verification data transmission instruction and performing the connectivity verification test based on whether or not verification data is successfully received through a test logical link indicated by a verification instruction; and
a control channel processing section for, when the a test logical link is indicated, notifying the end-point node through control channels that the connectivity verification test begins and outputting the verification data transmission instruction to the logical link verification processing section and, when notified through the control channels that the connectivity verification test begins, outputting the verification instruction to the logical link verification processing section, and transmitting a test result to the start-point node of the test logical link through control channels.
